(19) United States
(12) Patent Application Publication
(10) Pub. No.: US 2026/0328260 A1
(43) Pub. Date: Oct. 22, 2026

(54) SIX-DEGREE-OF-FREEDOM PASSIVE VIBRATION ISOLATOR

(71) Applicant: Zhejiang University, Hangzhou (CN)

(72) Inventors: Wen He, Hangzhou, Zhejiang (CN); Bohan Shen, Hangzhou, Zhejiang (CN); Tao Song, Hangzhou, Zhejiang (CN); Jie Zhou, Hangzhou, Zhejiang (CN)

(21) Appl. No.: 19/182,546

(22) Filed: Apr. 17, 2025

(51) Int. Cl. F16F 15/067; G06F 30/17

(52) U.S. Cl. CPC F16F 15/067; G06F 30/17; F16F 2230/186

(57) ABSTRACT

The present application relates to a six-degree-of-freedom passive vibration isolator, disclosing a design scheme for a quasi-zero-stiffness six-degree-of-freedom passive vibration isolator based on a compression spring structure and an Euler compression rod structure. Firstly, the quasi-zero stiffness characteristics of the compression spring structure in the vertical direction are analyzed, and a design scheme for quasi-zero stiffness in the swing direction is disclosed and analyzed. Secondly, the quasi-zero stiffness characteristics of the Euler compression rod structure in the horizontal direction are analyzed, and stiffness characteristics thereof in the torsional direction are also analyzed. Finally, a six-degree-of-freedom passive vibration isolation model based on the compression spring structure and the Euler compression rod structure is disclosed.

### FIELD OF THE INVENTION

The present application relates to the technical field of vibration control, and in particular to, to a six-degree-of-freedom passive vibration isolator.

### BACKGROUND OF THE INVENTION

Presently, a large number of steel spring vibration isolators with single degree of freedom, two degrees of freedom of translation and rotation, and three degrees of freedom of translation. These vibration isolators can effectively isolate vibration in a certain interference environment, but cannot play a role in isolating vibration in a more complex vibration interference environment.

Vibration isolators are widely used in a number of applications, such as test equipment and protective equipment, etc. Multi-degree-of-freedom passive vibration isolators are often used in the fields of coupling testing, coupling protection, etc. Since conventional multi-degree-of-freedom passive vibration isolators are mostly used to simulate microgravity environments, more importance is attached to the analysis of passive devices and the application of analysis results in the fields of coupling testing and coupling protection, etc. Conventional multi-degree-of-freedom passive vibration isolators are often more complex, which causes difficult applications of conventional multi-degree-of-freedom passive vibration isolators. For this purpose, it is necessary to provide a six-degree-of-freedom passive vibration isolator to address the shortcomings of conventional multi-degree-of-freedom passive vibration isolators, which are complex in structure and difficult to analyze, resulting in difficulty in applications.

### SUMMARY OF THE INVENTION

In view of this, it is necessary to provide a six-degree-of-freedom passive vibration isolator to address the shortcomings of conventional multi-degree-of-freedom passive vibration isolators, which are complex in structure and difficult to analyze, resulting in difficulty in applications.

The present application relates to a method for applying the six-degree-of-freedom passive vibration isolator, comprising:
judging the working mode of a vibration isolation model by utilizing static stiffness characteristics and dynamic stiffness characteristics within quasi-zero stiffness characteristics of the vibration isolation model to obtain the working mode of the vibration isolation model;
judging whether the static stiffness characteristics of the vibration isolation model match the degrees of freedom of the vibration isolation model based on the working mode of the vibration isolation model to obtain the type of the vibration isolation model;
extracting all types of vibration isolation models, including a passive vibration isolation system in an active vibration isolation system model and a hybrid vibration isolation system model;
incorporating the passive vibration isolation system and the passive vibration isolation system model into the quasi-zero-stiffness analysis algorithm to obtain an adaptive structural parameter system for degree-of-freedom analysis;
generating a coupling effect characteristic equation based on the adaptive structural parameter system for degree-of-freedom analysis;
generating a degree-of-freedom passive vibration isolator by utilizing the coupling effect characteristic equation.

The present application relates to a six-degree-of-freedom passive vibration isolator, comprising:
a housing, configured with a top opening, a closed bottom, and an inner cavity, wherein the housing comprises a base plate, a plurality of slide rails are arranged on the inner wall of the housing near the top surface of the housing, a support plate is fixedly connected to the inner wall of the housing near the bottom surface of the housing, the support plate and the base plate are in parallel;
each of the slide rails extends in a direction parallel to the central axis of the housing, and is attached to and fixedly connected to the inner wall of the housing;
a support platform, configured as a circular plate, and disposed on the support plate, wherein a plurality of first through holes are formed in the support platform, the first through holes are arranged circumferentially around the central axis of the support platform; a plurality of second through holes are formed in the support platform, the second through holes are arranged circumferentially around the central axis of the support platform;
an adjustment platform, configured as a circular plate, and provided with right-angle connecting pieces, wherein the adjustment platform is slidably connected to the slide rails through the right-angle connecting pieces; a plurality of third through holes are formed in the adjustment platform, the third through holes are arranged circumferentially around the central axis of the adjustment platform; a plurality of fourth through holes are formed in the adjustment platform, the fourth through holes are arranged circumferentially around the central axis of the adjustment platform;
a main platform, accommodated within the inner cavity, wherein a plurality of fifth through holes are formed in the main platform;
a vertical spring, wherein the main platform is fixedly connected to the adjustment platform through the vertical spring;
the first through holes, the third through holes, and the fifth through holes are located on a straight line parallel to the central axis of the housing;
the second through holes and the fourth through holes are located on another straight line parallel to the central axis of the housing;
a secondary platform, accommodated within the inner cavity of the housing;
a vertical connecting rod, accommodated within the second through holes and the fourth through holes, wherein the secondary platform is fixedly connected to the main platform through the vertical connecting rod;
a tabletop, located outside the housing;
An Euler compression rod, accommodated within the first through holes, the third through holes, and the fifth through holes, wherein the tabletop is fixedly connected to the secondary platform through the Euler compression rod;
a plurality of horizontal adjustment mechanisms, each connected to the main platform;
a vertical adjustment mechanism, located between the adjustment platform and the support platform.

The present application relates to a six-degree-of-freedom passive vibration isolator, disclosing a design scheme for a quasi-zero-stiffness six-degree-of-freedom passive vibration isolator based on a compression spring structure and an Euler compression rod structure. Firstly, the quasi-zero stiffness characteristics of the compression spring structure in the vertical direction are analyzed, and a design scheme for quasi-zero stiffness in the swing direction is disclosed and analyzed. Secondly, the quasi-zero stiffness characteristics of the Euler compression rod structure in the horizontal direction are analyzed, and stiffness characteristics thereof in the torsional direction are also analyzed. Finally, a six-degree-of-freedom passive vibration isolation model based on the compression spring structure and the Euler compression rod structure is disclosed, a spatial coordinate transformation method is adopted to decouple and analyze the deformation of flexible components, the force analysis of vibration isolation components of the six-degree-of-freedom passive vibration isolation model is conducted, and the six-degree-of-freedom stiffness at the equilibrium position of the vibration isolator is solved, providing a theoretical basis for the subsequent mechanical structure design and vibration isolation characteristics analysis of the quasi-zero-stiffness six-degree-of-freedom passive vibration isolator.

### BRIEF DESCRIPTION OF THE DRAWINGS

FIG. 1 is a structural schematic diagram of a passive vibration isolation model of a six-degree-of-freedom passive vibration isolator provided in an embodiment of the present application.

FIG. 2 is a structural schematic diagram of an active vibration isolation model of a six-degree-of-freedom passive vibration isolator provided in an embodiment of the present application.

FIG. 3 is a structural schematic diagram of a hybrid vibration isolation model of a six-degree-of-freedom passive vibration isolator provided in an embodiment of the present application.

FIG. 4 is a half-section view of a six-degree-of-freedom passive vibration isolator provided in an embodiment of the present application.

FIG. 5 is an enlarged view of A provided in an embodiment of the present application.

FIG. 6 is a structural diagram of a six-degree-of-freedom passive vibration isolator with housing hidden provided in an embodiment of the present application.

FIG. 7 is a structural diagram of a six-degree-of-freedom passive vibration isolator with housing hidden provided in an embodiment of the present application.

FIG. 8 is a cross-sectional view representing a connection between a housing and a base plate of a six-degree-of-freedom passive vibration isolator provided in an embodiment of the present application.

FIG. 9 is a flow diagram of a method for applying a six-degree-of-freedom passive vibration isolator provided in an embodiment of the present application.

### REFERENCE NUMERALS

100—housing; 110—top surface; 120—bottom surface; 130—slide rail; 131—sliding block;
140—support plate; 150—threaded through hole; 160—eighth through hole; 200—support platform;
210—first through hole; 220—second through hole; 230—seventh through hole; 300—adjustment platform;
310—right-angle connecting pieces; 320—third through hole; 330—fourth through hole; 340—sixth through hole;
400—main platform; 410—vertical spring; 420—fifth through hole; 500—secondary platform; 510—vertical connecting rod;
600—tabletop; 610—Euler compression rod; 700—horizontal adjustment mechanism; 710—first revolute joint connecting piece;
711—first rotating shaft; 720—second revolute joint connecting piece; 721—second rotating shaft;
730—horizontal damping spring; 731—outer guide cylinder; 731a—third revolute joint connecting piece; 732—inner guide cylinder;
732a—fourth revolute joint connecting piece; 733—horizontal spring; 740—horizontal knob; 750—fastening nut;
800—vertical adjustment mechanism; 810—worm gear; 820—feed screw rod; 830—linear bearing;
840—shaft seat; 850—worm; 860—knob; 861—locking screw; 870—coupling;
880—sphere-pin pair; 881—prismatic pair; 900—base plate; 910—ninth through hole.

### DETAILED DESCRIPTION

In order to illustrate the object, technical solutions and advantages of the present application more clearly, the present application will be further described in detail below in conjunction with accompanying drawings and embodiments. It should be understood that the specific embodiments described herein are merely used to explain the present application and are not used to limit the present application.

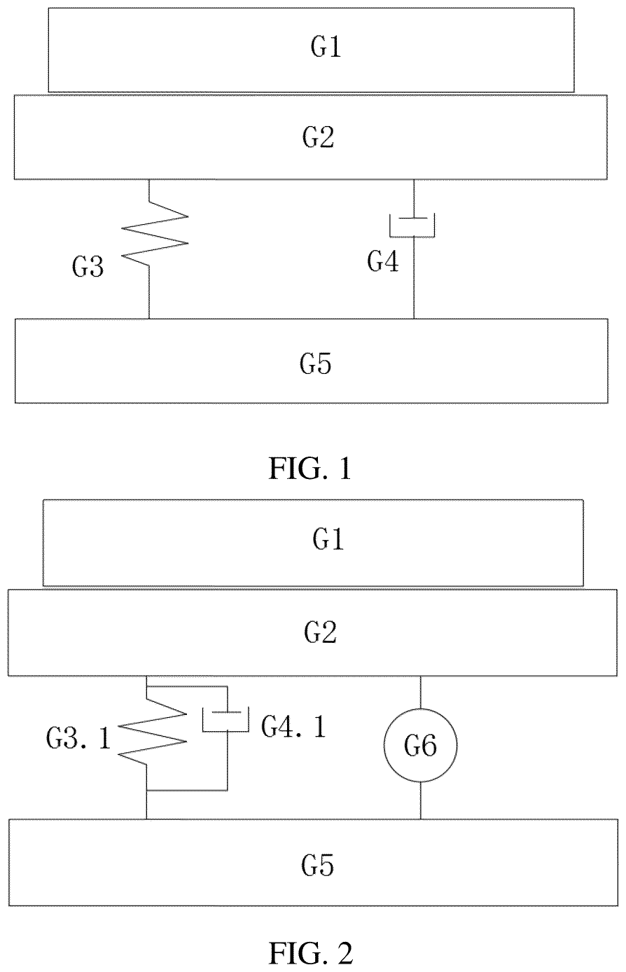

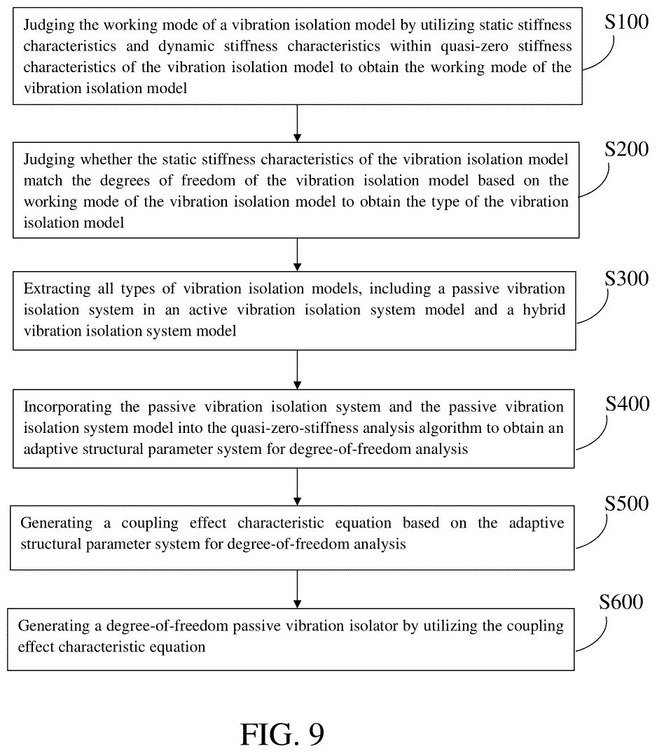

Referring to FIGS. 1-9, in particular, as shown in FIG. 9, in an embodiment of the present application, a method for applying a six-degree-of-freedom passive vibration isolator is provided, including:
S100, judging the working mode of a vibration isolation model by utilizing static stiffness characteristics and dynamic stiffness characteristics within quasi-zero stiffness characteristics of the vibration isolation model to obtain the working mode of the vibration isolation model.
S200, judging whether the static stiffness characteristics of the vibration isolation model match the degrees of freedom of the vibration isolation model based on the working mode of the vibration isolation model to obtain the type of the vibration isolation model.
S300, extracting all types of vibration isolation models, including a passive vibration isolation system in an active vibration isolation system model and a hybrid vibration isolation system model.
S400, incorporating the passive vibration isolation system and the passive vibration isolation system model into the quasi-zero-stiffness analysis algorithm to obtain an adaptive structural parameter system for degree-of-freedom analysis.
S500, generating a coupling effect characteristic equation based on the adaptive structural parameter system for degree-of-freedom analysis.
S600, generating a degree-of-freedom passive vibration isolator by utilizing the coupling effect characteristic equation.

Specifically, the coupling effect characteristic equation applies a quasi-zero-stiffness analysis algorithm. The quasi-zero-stiffness analysis algorithm includes a vertical spring analysis equation, a horizontal adjustment mechanism analysis equation, a main platform assembly analysis equation, an Euler compression rod mechanism analysis equation and a vertical adjustment mechanism analysis equation.

According to the differences in the working modes of the vibration isolation system, the commonly used vibration isolation technologies can be divided into three categories, namely passive vibration isolation, active vibration isolation and hybrid vibration isolation.

Passive vibration isolation technology is the earliest and most developed vibration isolation technology. This technology primarily makes use of springs and damping for vibration isolation. Commonly used vibration isolation methods such as spiral springs, wire ropes, air springs, rubber pads belong to passive vibration isolation. The main advantages are simple structure, high reliability, no need for external energy, and good vibration isolation effect for high-frequency vibration interference.

Active vibration isolation technology is a vibration isolation method that controls an actuator through an external controller. An active vibration isolation system includes a load, a vibration isolation platform, a controller, a sensor, an actuator and a foundation. The essence of the technology is to generate a signal opposite to the excitation signal through a control system, and control an actuator to output reverse vibration to offset the interference of the excitation source.

Hybrid vibration isolation technology is also called semi-active vibration isolation technology, including two forms: variable damping and variable stiffness. Magnetorheological damping isolators are a more common hybrid vibration isolation method. When the vibration interference to the system is constantly changing, a hybrid vibration isolation system can change the stiffness and damping parameters of the system through the controller, and adjust the vibration isolation characteristics of the isolator itself to adapt to different environments. Since the changes in stiffness and damping cause the natural frequency of the isolator itself to change, the system will never resonate. Hybrid vibration isolation technology combines the advantages of passive vibration isolation and active vibration isolation, but it still requires external energy and the system is more complex. By comparing the three basic vibration isolation methods, passive vibration isolation has the advantages of simple structure, no need for external energy, easy mobility and good high-frequency characteristics, and has been widely used in the field of vibration isolation of high-precision instruments such as mobile devices.

When the vibration interference to a base is xₛ=A sin ωt, if the vibration isolation object with mass m is directly connected to the base, the system does not have the vibration isolation function, and the motion form of the vibration isolation object is exactly the same as that of the base. If a spring with stiffness k and a damping material with damping c are added between the vibration isolation object and the base, a mass-spring damping passive vibration isolation system is formed. The dynamic equation of the passive vibration isolation system is:

m\ddot{x}+c(\dot{x}−\dot{x}ₛ)+k(x−xₛ)=0. (1.1)

By solving the differential equation using the complex number method, the modulus of the vibration displacement transfer function from the system base to the vibration isolation object can be obtained as:

$$\vert \frac{X}{{X}_{s}} \vert = \sqrt{\frac{1 + {( 2 ζω / {ω}_{n} )}^{2}}{{( 1 - {ω}^{2} / {ω}_{n}^{2} )}^{2} + {( 2 ζω / {ω}_{n} )}^{2}}} , \qquad ( 1.2 )$$

Where: ω is the vibration frequency of the base, ωₙ is the undamped natural frequency of the system, referred to as the natural frequency, and is calculated as ωₙ=\sqrt{k/m}, ζ is the system damping ratio and is calculated as ζ=c/(2\sqrt{mk}). In the amplitude-frequency response curve of the passive vibration isolation system, the peak frequency is the damped natural frequency of the system, and is calculated as ω_{d}=\sqrt{1−2ζ²}ωₙ. When the system damping is very small, the damped natural frequency is not much different from the undamped natural frequency. When the frequency is equal to \sqrt{2}ωₙ, the vibration transmission rate is equal to 1, and the system begins to play a vibration isolation role. This frequency is called the cutoff frequency ω_{c}. When the system natural frequency ωₙ decreases, the peak frequency point moves to the left, and the cutoff frequency ω_{c} moves to the left accordingly. The vibration isolation frequency band of the system is widened, and the low-frequency vibration isolation effect is improved. Therefore, reducing the system natural frequency is an effective way to improve the low-frequency vibration isolation effect of passive vibration isolation technology.

According to the cutoff frequency ω_{c}=\sqrt{2k/m} of the system, it can be inferred that, when the load mass m is constant, the system stiffness must be reduced to lower the natural frequency ωₙ and cutoff frequency ω_{c} of the system and optimize the low-frequency vibration isolation effect of the passive vibration isolation technology. However, in actual applications, the vibration isolation object in the passive vibration isolator has a certain weight, and the load weight needs to be supported by the elastic structure of the vibration isolation system. A low-stiffness system will cause excessive static displacement of the system to lose stability, which is opposite to the goal of improving the vibration isolation ability by reducing the stiffness. Based on the design consideration of the load capacity and vibration isolation performance, in order to solve the contradiction between the load capacity and vibration isolation effect of the passive vibration isolation system, the positive and negative stiffness parallel method is generally used to design the passive vibration isolation system. In general, the force required to produce a unit displacement is defined as stiffness. When the force increases with the increase in the displacement, the stiffness is positive. When the force does no change with the change in the displacement, the stiffness is zero. When the force decreases with the increase in the displacement, the stiffness is negative.

For the quasi-zero-stiffness vibration isolation model with positive and negative stiffness parallel, in the equilibrium position, the linear positive stiffness spring provides a support force F_{μl} for the load, which is balanced with the load gravity G, and the nonlinear negative stiffness spring is at its original length and has no force on the load. In the non-equilibrium position, the negative stiffness spring deforms, and the direction of its spring force Fₙ is the same as the load displacement. The force and stiffness of the load in the quasi-zero-stiffness vibration isolation model change with the displacement. The static stiffness characteristics of the parallel system near the equilibrium position are not much different from those of the positive stiffness spring, having a very high load capacity. Meanwhile, the dynamic quasi-zero stiffness characteristics are realized, so that the system has an extremely low natural frequency near the equilibrium position. Therefore, the quasi-zero-stiffness vibration isolation system with positive and negative stiffness parallel has high static stiffness and low dynamic stiffness characteristics, thereby achieving good load capacity and vibration isolation performance. In actual applications, usually some special structures are required to achieve nonlinear negative stiffness springs.

The spatial six-degree-of-freedom passive vibration isolation function of the vibration isolator can be achieved in this embodiment. The six-degree-of-freedom passive vibration isolation principle is analyzed, a six-degree-of-freedom passive vibration isolation model is established, and the mechanical structure of the vibration isolator is reasonably designed so that the vibration isolator has the spatial six-degree-of-freedom vibration isolation characteristics. The spatial six-degree-of-freedom vibration isolation effect of the vibration isolator is improved. To achieve the goal of low stiffness, the structural parameters are optimized, the cross-coupling effect of the vibration isolator are analyzed, the maximum vibration isolation amplitude of the vibration isolator is determined, and the vibration isolation performance of the vibration isolator is analyzed through simulation. The flexibility and adaptability of the six-degree-of-freedom passive vibration isolator are improved. The mechanical structure of the vibration isolator is designed reasonably to meet the vibration isolation requirements of the six-degree-of-freedom passive vibration isolator, such as small size, light weight, and adjustable multi-degree-of-freedom parameters. The vibration isolation effect of the designed six-degree-of-freedom passive vibration isolator is verified by experiments. Experimental research is carried out on the six-degree-of-freedom vibration isolation performance of the vibration isolator, and the six-degree-of-freedom vibration isolation performance of the vibration isolator is tested under actual working conditions to verify the correctness of the theoretical and simulation results.

The compression spring structure and the Euler compression rod structure are quasi-zero stiffness structures with excellent vibration isolation performance. Based on the vertical quasi-zero stiffness characteristics of a compression spring structure, the quasi-zero stiffness of the compression spring structure in the swing direction can improve the vibration isolation performance. Based on the horizontal quasi-zero stiffness characteristics of an Euler compression rod structure, the Euler compression rod structure is applied to the torsional vibration isolation scheme. By connecting the compression spring structure and the Euler compression rod structure in series, a quasi-zero-stiffness six-degree-of-freedom passive vibration isolation model is provided. The deformation of the flexible component is solved by the spatial coordinate transformation method, and the six-degree-of-freedom force and stiffness of the model are analyzed, providing a theoretical basis for the subsequent mechanical structure design and vibration isolation characteristics analysis of the quasi-zero-stiffness six-degree-of-freedom passive vibration isolator.

The spatial six-degree-of-freedom interference includes six directions, i.e., translations along the X-axis, Y-axis, and Z-axis, and rotation around the X-axis, Y-axis, and Z-axis. For the convenience of analysis, the movements of the same nature are combined: the translations along the X-axis and Y-axis are called the horizontal direction, the translation along the Z-axis is called the vertical direction, the rotations around the X-axis and Y-axis are called the swing direction, and the rotation around the Z-axis is called the torsion direction. The compression spring structure is mainly composed of a tabletop, a base, a vertical spring, and a horizontal spring. The compression spring structure is used for vertical vibration isolation. The vertical spring and the horizontal spring provide positive and negative stiffness, respectively. The vertical spring stiffness is kᵥ, the horizontal spring stiffness kₕ, the distance between the horizontal spring and the connection point between the base and the tabletop is L_{z}, that is, the length of the horizontal spring connecting piece, and the horizontal component is always Lₕ, the vertical component is the vertical displacement z of the tabletop. The vertical upward direction is specified as the positive direction. The tabletop has two states: equilibrium position and non-equilibrium position.

In the equilibrium position, when the tabletop is in the equilibrium position, the tabletop displacement is Z=0, the horizontal spring remains horizontal, the vertical spring pressure is equal to the tabletop gravity, the length of the horizontal spring connecting piece is Lₕ, the pre-compression amount of the horizontal spring is δ, and the combined force of the two horizontal springs on the tabletop is zero.

In the non-equilibrium position, when the tabletop is in the non-equilibrium position, the horizontal spring tilts, the vertical displacement of the tabletop is z; according to the geometric relationship, the length of the horizontal spring connecting piece is

$${L}_{z} = \sqrt{{L}_{h}^{2} + {z}^{2}} .$$

The effect of the spring force on the tabletop in the non-equilibrium position is:

F_{z}=Fₚ+Fₙ, (2.1)

where, Fₚ is the force generated by the vertical spring, according to Hooke's law:

Fₚ=2kᵥz; (2.2)

Fₙ is the force generated by the horizontal spring, according to Hooke's law and geometric relationship:

Fₙ=2kₕΔl sin θ, (2.3)

where, the compression amount of the horizontal spring is

$$Δ I = ( {L}_{h} + δ - {L}_{z} ) , sin θ = z / \sqrt{{L}_{h}^{2} + {z}^{2}} .$$

According to equations (2.1), (2.2) and (2.3), the vertical force on the tabletop can be obtained as:

$${F}_{z} = 2 {k}_{v} z - 2 {k}_{h} [ \frac{( {L}_{h} + δ ) z}{\sqrt{{L}_{h}^{2} + {z}^{2}}} - z ] . \qquad ( 2.4 )$$

Therefore, the vertical stiffness of the structure is:

$${k}_{z} = \frac{dF}{dz} = 2 {k}_{v} - 2 {k}_{h} [ \frac{( {L}_{h} + δ ) {L}_{h}^{2}}{{( {L}_{h}^{2} + {z}^{2} )}^{3 / 2}} - 1 ] . \qquad ( 2.5 )$$

It can be found that the vertical force and stiffness of the compression spring structure are jointly determined by Lₕ, δ, Kₕ and Kᵥ, and the vertical force and stiffness change nonlinearly with respect to the vertical displacement z. The vertical stiffness of the vibration isolation model can be changed by changing the structural parameters, so that the vertical stiffness of the tabletop near the equilibrium position is always less than the linear positive stiffness generated by the vertical spring, and the quasi-zero stiffness characteristic of the compression spring structure in parallel with the vertical spring and the horizontal spring is realized to play a vibration isolation role.

The compression spring structure not only has the quasi-zero stiffness characteristics both in the vertical direction and in the swing direction. The vibration isolation scheme of the compression spring structure in the swing direction is provided. In the vibration isolation model, the vertical spring provides positive stiffness and the horizontal spring provides negative stiffness. As long as the parameters are reasonably configured, the quasi-zero stiffness characteristic in the swing direction can be achieved.

The distance from the connection point between the horizontal spring and the tabletop to the center of the tabletop is Rₕ, and the distance from the connection point between the vertical spring and the tabletop to the center of the tabletop is Rᵥ. The swing of the compression spring structure also has two states: equilibrium position and non-equilibrium position. Its equilibrium position is the same as the equilibrium position in the vertical vibration isolation analysis. The non-equilibrium position is the position where the tabletop swings with an inclination angle θ when disturbed by the swing. The counterclockwise direction is stipulated as the positive direction of the swing. At this time, the two horizontal springs both have a deflection angle of φ and are still in a compressed state, while the two vertical springs extend and contract at the same time.

The torque of the spring acting on the tabletop is:

M_{θ}=Mₚ−Mₙ, (2.6)

Where Mₚ is the torque generated by the vertical spring, and is calculated as:

$${M}_{p} = 2 {k}_{v} {R}_{v}^{2} sin θ ; \qquad ( 2.7 )$$

is the torque generated by the horizontal spring, and is calculated as:

Mₙ=2Fₙ1, (2.8)

Where Fₙ is the force generated by the vertical spring, which can be expressed as Fₙ=kₕΔx according to Hooke's law, where Δx is the deformation of the vertical spring, which can be expressed as Δx=δ−(Rₕ sin θ/sin φ−Lₕ) according to the geometric relationship, and the force arm of Fₙ is 1=(a+Rₕ)sin φ, where:

$$sin φ = \frac{{R}_{h} sin θ}{\sqrt{{( {R}_{h} sin θ )}^{2} + {( {L}_{h} + {R}_{h} - {R}_{h} cos θ )}^{2}}} . \qquad ( 2.9 )$$

According to the equations (2.6), (2.7), (2.8), and (2.9), the moment acting on the tabletop can be calculated as:

$${M}_{θ} = 2 {k}_{v} {R}_{v}^{2} sin θ - 2 {k}_{h} ( {L}_{h} + {R}_{h} ) [ \frac{( δ + {L}_{h} ) {R}_{h} sin θ}{\sqrt{{( {R}_{h} sin θ )}^{2} + {( {L}_{h} + {R}_{h} - {R}_{h} cos θ )}^{2}}} - {R}_{h} sin θ ] . \qquad ( 2.1 )$$

When the value of θ is very small, sin θ≈θ, 1−cos θ≈θ²/2≈0; based on this, a small amount of approximation can simplify the equation (2.10) to:

$${M}_{θ} \approx 2 {k}_{v} {R}_{v}^{2} θ - 2 {k}_{h} ( {L}_{h} + {R}_{h} ) [ \frac{( δ + {L}_{h} ) {R}_{h} θ}{\sqrt{{( {R}_{h} θ )}^{2} + {L}_{h}^{2}}} - {R}_{h} θ ] , \qquad ( 2.11 )$$

Thus, the swing stiffness of the structure is calculated as:

$${k}_{θ} = 2 {k}_{v} {R}_{v}^{2} - 2 {k}_{h} ( {L}_{h} + {R}_{h} ) {R}_{h} [ \frac{( δ + {L}_{h} ) {L}_{h}^{2}}{{( {R}_{h}^{2} {θ}^{2} + {L}_{h}^{2} )}^{3 / 2}} - 1 ] . \qquad ( 2.12 )$$

It can be found that the force and stiffness in the swing direction are related to 6 parameters, i.e. Rᵥ, Rₕ, Lₕ, δ, kₕ and kᵥ. The parameters Lₕ, δ, kₕ, kᵥ also affect the force and stiffness in the vertical direction, and needs to be considered simultaneously in the optimization analysis. The swing stiffness k_{θ} is an even function, and changes nonlinearly with respect to the rotation angle θ. By optimizing the parameters, the swing stiffness is closed to zero within a certain displacement range near the equilibrium position, and is smaller than the original vertical spring positive stiffness, thus achieving the quasi-zero stiffness characteristic in the swing direction.

In FIG. 1, G1 is the load 1, G2 is the vibration isolation platform 1, G3 is the spring 1, G4 is the damper 1, and G5 is the foundation 1.

In FIG. 2, G1 is the load 1, G2 is the vibration isolation platform 1, G3.1 is the spring 2, G4.1 is the damper 2, G5 is the foundation 1, and G6 is the actuator 1.

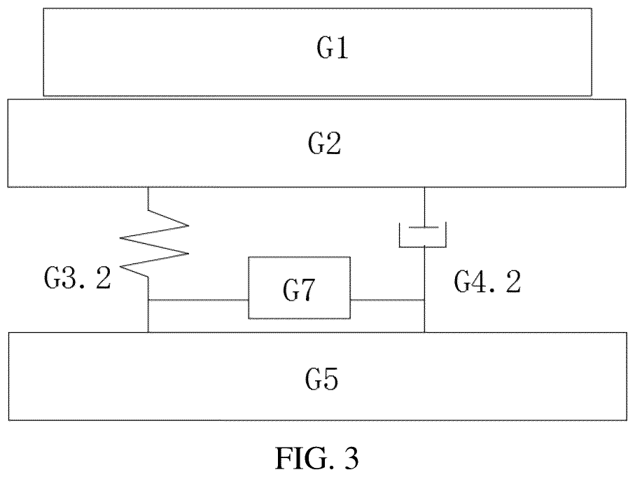

In FIG. 3, G1 is the load 1, G2 is the vibration isolation platform 1, G3.2 is the spring 3, G4.2 is the damper 3, G5 is the foundation 1, and G7 is the regulator 1, and regulator 1 is used to adjust the parameters of the spring 3 and the damper 3.

As shown in FIG. 1 to FIG. 3, in an embodiment of the present application, a method for applying a six-degree-of-freedom passive vibration isolator includes:
judging whether an applied vibration isolation model is a passive vibration isolation model based on a target application scenario.

Specifically, determining a load type based on the target application scenario; determining a load type, selecting the parameters of a vibration isolation platform based on the load type, selecting the vibration isolation model using the parameters of the vibration isolation platform.

Passive vibration isolation technology primarily uses springs and damping for vibration isolation; commonly used vibration isolation methods include spiral springs, wire ropes, air springs, rubber pads, etc., which have a simple structure, high reliability, and need no external energy, and have a good vibration isolation effect on high-frequency vibration interference. The load types are widely used in aerospace engineering, vehicle engineering, power engineering, civil engineering, precision engineering, etc. Passive vibration isolation technology is used in aerospace engineering, vehicle engineering, power engineering, civil engineering, precision engineering, etc., especially with the constant development of high-end precision technology, the environmental requirements for optical photography, precision machining and measurement, aerospace and other fields are constantly increasing. It is necessary to effectively suppress and isolate the vibrations in these occasions, thereby improving the data accuracy and movement precision.

More specifically, judging whether a vibration isolation platform linkage feature of the selected vibration isolation model has a fixed connection feature; if the vibration isolation platform linkage feature of the selected vibration isolation model does not have a fixed connection feature, determining that the quasi-zero stiffness characteristics of the vibration isolation model are less than the quasi-zero stiffness accuracy in quasi-zero stiffness applications; if the selected vibration isolation model has a fixed connection feature, further judging whether the vibration isolation platform of the selected vibration isolation model has a follow-up characteristic; if the vibration isolation platform of the selected vibration isolation model does not have a follow-up characteristic, determining an actuator adapted to the vibration isolation model so that a numerical value of the quasi-zero stiffness characteristics of the vibration isolation model is greater than or equal to the quasi-zero stiffness accuracy in quasi-zero stiffness applications; if the vibration isolation platform of the selected vibration isolation model has a follow-up characteristic, determining that the numerical value of the quasi-zero stiffness characteristics of the vibration isolation model is greater than or equal to the quasi-zero stiffness accuracy in quasi-zero stiffness applications.

Actually, the linkage characteristics of the vibration isolation platform of the vibration isolation model involve the kinematic pair characteristics in the quasi-zero-stiffness six-degree-of-freedom passive vibration isolator. The quasi-zero-stiffness six-degree-of-freedom passive vibration isolator includes one or more of a revolute pair, a prismatic pair, a sphere-pin pair and a cylinder pair.

The fixed connection feature can be reflected in the kinematic pair characteristics such as the prismatic pair and the cylinder pair. The follow-up characteristic may be reflected more obviously in the kinematic pair characteristics of the revolute pair, the prismatic pair and the sphere-pin pair.

It is worth mentioning that the quasi-zero stiffness characteristics are based on the physical quantities such as position, displacement, acceleration, and force in space, which can be expressed by vectors in the spatial rectangular coordinate system. Usually, a global coordinate system fixedly connected to the earth and a local coordinate system fixedly connected to each component itself are established to determine these vectors. Coordinate transformation is the process of transforming from one coordinate system to another. By establishing a corresponding relationship between two coordinate systems, the mutual transformation of physical quantities among the local coordinate systems of each component, between the local coordinate systems of each component and the global coordinate system can be realized.

In fact, more effective applications of the quasi-zero stiffness accuracy in quasi-zero stiffness applications are the determination of quasi-zero stiffness, determination of quasi-zero stiffness accuracy, and construction process of quasi-zero stiffness accuracy.

The determination of quasi-zero stiffness includes vibration isolation dimension, load range, vibration isolation frequency band, vibration displacement attenuation rate, etc.

The determination of quasi-zero stiffness accuracy includes the weight, volume, and adjustable parameters of the vibration isolator, etc.

The construction process of quasi-zero stiffness accuracy is based on the goal of quasi-zero-stiffness six-degree-of-freedom passive vibration isolator. The goal of quasi-zero-stiffness six-degree-of-freedom passive vibration isolator is, for example, a lower six-degree-of-freedom natural frequency. The six-degree-of-freedom low-frequency vibration isolation performance is good. The quasi-zero stiffness characteristics are still maintained within a certain displacement range near the equilibrium position, and the stiffness nonlinearity of the vibration isolator is weak.

If the vibration isolation model is a passive vibration isolation model, a passive vibration isolation system model is established.

Specifically, determining an equilibrium position of the vibration isolation model based on the quasi-zero stiffness characteristics of the vibration isolation model; determining the positive and negative stiffness parallel characteristics of the vibration isolation model using the equilibrium position of the vibration isolation model; analyzing the static stiffness characteristics and dynamic stiffness characteristics of the quasi-zero stiffness characteristics of the vibration isolation model based on the positive and negative stiffness parallel characteristics of the vibration isolation model.

The vibration isolation models include a passive vibration isolation model, an active vibration isolation model and a hybrid vibration isolation model. The vibration isolation model is specifically applied to the passive vibration isolation system model, active vibration isolation system model and hybrid vibration isolation system model. Since the active vibration isolation system model has an actuator, an equilibrium position of the vibration isolation model can be determined based on the quasi-zero stiffness characteristics of the vibration isolation model.

The equilibrium position of the vibration isolation model has static stiffness characteristics and dynamic stiffness characteristics. The static stiffness characteristics and dynamic stiffness characteristics of the vibration isolation model will be fed back to the quasi-zero stiffness characteristics of the vibration isolation model. For example, in the nonlinear ultra-low frequency quasi-zero stiffness horizontal vibration isolation system based on the forward and inverted pendulum parallel structure, the forward pendulum has positive stiffness characteristics and the inverted pendulum has negative stiffness characteristics.

It is worth noting that after establishing a passive vibration isolation system model if the vibration isolation model is a passive vibration isolation model, the method for applying the six-degree-of-freedom passive vibration isolator further includes:
judging the working mode of a vibration isolation model by utilizing static stiffness characteristics and dynamic stiffness characteristics within quasi-zero stiffness characteristics of the vibration isolation model;
if the static stiffness characteristics of the vibration isolation model match the degrees of freedom of the vibration isolation model, further judging whether the coupling effect of the coupler of the vibration isolation model matches the dynamic stiffness characteristics; if the coupling effect of the coupler matches the dynamic stiffness characteristics, determining the vibration isolation model as a passive vibration isolation model; if the coupling effect of the coupler does not match the dynamic stiffness characteristics, determining the vibration isolation model as an active vibration isolation model; if the static stiffness characteristics of the vibration isolation model do not match the degrees of freedom of the vibration isolation model, further judging whether the coupler of the vibration isolation model matches the native characteristics of the vibration isolation model; if the coupler matches the native characteristics of the vibration isolation model, determining the vibration isolation model as a hybrid vibration isolation model; if the coupler does not match the native characteristics of the vibration isolation model, determining the vibration isolation model as an active vibration isolation model.

The degrees of freedom are reflected in the vibration isolation dimension, load range, vibration isolation frequency band, vibration displacement attenuation rate, etc., and also include the weight, volume, and adjustable parameters of the vibration isolator, etc.

Multiple degrees of freedom are the goal of the quasi-zero-stiffness six-degree-of-freedom passive vibration isolator. The goal of the quasi-zero-stiffness six-degree-of-freedom passive vibration isolator is, for example, a lower six-degree-of-freedom natural frequency. The six-degree-of-freedom low-frequency vibration isolation performance is good. The quasi-zero stiffness characteristics are still maintained within a certain displacement range near the equilibrium position, and the stiffness nonlinearity of the vibration isolator is weak.

The coupler has a coupling effect.

The coupler of the vibration isolation model can rely on its own structure. The couplers that rely on their own structures reflect the native characteristics of the vibration isolation model. The native characteristics of the vibration isolation model can be applied to the passive vibration isolation model and the hybrid vibration isolation model.

The coupler of the vibration isolation model can rely on an attached coupler. The couplers that rely on the external structures reflect the activeness of the vibration isolation model. The activeness of the vibration isolation model can be applied to the active vibration isolation model.

Due to the coupling effect of the coupler, the coupling effect characteristic equation will apply the passive vibration isolation system in the active vibration isolation system model and the hybrid vibration isolation system model. Due to the coupling effect of the coupler, the coupling effect characteristic equation will also apply the equilibrium characteristics of the vibration isolation model. The coupler of the vibration isolation model can reduce the difficulty of applying multiple degrees of freedom of the vibration isolator, thereby reducing the structure of the multi-degree-of-freedom passive vibration isolator, reducing the complexity of the multi-degree-of-freedom passive vibration isolator, and improving the simplicity of analysis of the multi-degree-of-freedom passive vibration isolator.

The working mode of the vibration isolation model includes one or more of a degree-of-freedom working mode, a load type working mode, or a coupler working mode.

If the vibration isolation model is an active vibration isolation model, further judging whether the vibration isolation model is an active vibration isolation system model;
if the vibration isolation model is an active vibration isolation system model, establishing an active vibration isolation system model;
if the vibration isolation model is not an active vibration isolation system model, establishing a hybrid vibration isolation system model;
extracting the passive vibration isolation system from the active vibration isolation system model and the hybrid vibration isolation system model.

Specifically, analyzing the vibration isolation of a compression spring quasi-zero stiffness structure in the passive vibration isolation system of the active vibration isolation system model and the hybrid vibration isolation system model; obtaining the native characteristics and coupling effect characteristics of the coupler; analyzing the vibration isolation of an Euler compression rod quasi-zero stiffness structure in the passive vibration isolation system of the active vibration isolation system model and the hybrid vibration isolation system model; obtaining degree-of-freedom adaptive structural parameters of the vibration isolation model; determining a quasi-zero-stiffness degree-of-freedom passive vibration isolation system analysis equation based on the adaptive structural parameters and the degree-of-freedom adaptive structural parameters of the vibration isolation model;
incorporating the passive vibration isolation system and the passive vibration isolation system model into the quasi-zero-stiffness analysis algorithm to obtain an adaptive structural parameter system for degree-of-freedom analysis.

Specifically, the quasi-zero-stiffness analysis algorithm includes a vertical spring analysis equation, a horizontal adjustment mechanism analysis equation, a main platform assembly analysis equation, an Euler compression rod mechanism analysis equation, and a vertical adjustment mechanism analysis equation.

A coupling effect characteristic equation is generated based on the adaptive structural parameter system for degree-of-freedom analysis.

Specifically, a degree-of-freedom passive vibration isolator is generated by utilizing the coupling effect characteristic equation.

The present application relates to a six-degree-of-freedom passive vibration isolator, disclosing a design scheme for a quasi-zero stiffness six-degree-of-freedom passive vibration isolator based on a compression spring structure and an Euler compression rod structure. Firstly, the quasi-zero stiffness characteristics of the compression spring structure in the vertical direction are analyzed, and a design scheme for quasi-zero stiffness in the swing direction is disclosed and analyzed. Secondly, the quasi-zero stiffness characteristics of the Euler compression rod structure in the horizontal direction are analyzed, and stiffness characteristics thereof in the torsional direction are also analyzed. Finally, a six-degree-of-freedom passive vibration isolation model based on the compression spring structure and the Euler compression rod structure is disclosed, a spatial coordinate transformation method is adopted to decouple and analyze the deformation of flexible components, the force analysis of vibration isolation components of the six-degree-of-freedom passive vibration isolation model is conducted, and the six-degree-of-freedom stiffness at the equilibrium position of the vibration isolator is solved, providing a theoretical basis for the subsequent mechanical structure design and vibration isolation characteristics analysis of the quasi-zero stiffness six-degree-of-freedom passive vibration isolator.

A mechanical structure of the six-degree-of-freedom passive vibration isolator based on the quasi-zero stiffness structure is designed. Firstly, the technical indicators of the quasi-zero-stiffness six-degree-of-freedom passive vibration isolator are provided, and the overall design of the vibration isolator is carried out according to the designed six-degree-of-freedom passive vibration isolation model. Secondly, taking the six-degree-of-freedom stiffness of the quasi-zero-stiffness six-degree-of-freedom passive vibration isolator at the equilibrium position as an objective function, a multi-objective optimization design of the structural parameters related to the vibration isolation characteristics is carried out; finally, the structural design of the vibration isolation components and the fixed components of the quasi-zero-stiffness six-degree-of-freedom passive vibration isolator is completed respectively, the static and dynamic analysis of key components in the vibration isolation components is conducted, and the static and dynamic analysis of fixed components of the vibration isolator is conducted.

The vibration isolation characteristics of the six-degree-of-freedom passive vibration isolator based on the quasi-zero stiffness structure are analyzed. Firstly, the sensitivity of the six-degree-of-freedom stiffness of the quasi-zero-stiffness six-degree-of-freedom passive vibration isolator to displacement is studied theoretically, and the influence of this cross-coupling characteristic on the vibration isolation effect is analyzed. It is inferred that the theoretical natural frequency ranges of the isolator in the horizontal, vertical, swing, and torsional directions are [1.69 Hz, 1.75 Hz], [0.36 Hz, 3.47 Hz], [0.37 Hz, 2.62 Hz], and [1.89 Hz, 2.01 Hz], respectively. The natural frequencies of the isolator in the horizontal, vertical, swing and torsional directions are 1.9 Hz, 1.6 Hz, 1.3 Hz and 2.0 Hz, respectively, the cut-off frequencies for the start of vibration isolation are 3.1 Hz, 2.6 Hz, 2.6 Hz and 2.8 Hz, respectively, and the frequencies for attenuation of 20 dB are 5.7 Hz, 10.2 Hz, 5.1 Hz and 6.6 Hz, respectively, which meet the design specifications.

The weight of the vibration isolator is 10.2 kg. The vertical table, horizontal table, angle table and swing table are used to generate vibration excitation. The single-degree-of-freedom vibration quantity of the vibration isolator is tested to obtain its acceleration transmissibility frequency response characteristics and verify the correctness of the theoretical and simulation results. The natural frequencies of the vibration isolator in the horizontal, vertical, swing and torsional directions are 2.0 Hz, 1.7 Hz, 1.5 Hz and 2.1 Hz, respectively, all of which are less than 2.5 Hz. The cutoff frequencies for the start of vibration isolation are 3.2 Hz, 2.6 Hz, 3.1 Hz and 3.4 Hz, respectively. The frequencies for attenuation of 20 dB are 7.1 Hz, 11.1 Hz, 8.1 Hz and 8.5 Hz, respectively, which meet the design specifications.

The present application provides a six-degree-of-freedom passive vibration isolator.

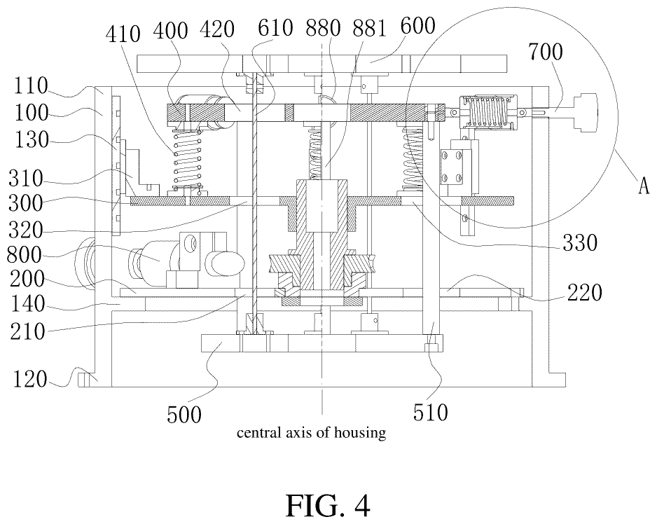

As shown in FIG. 4, in an embodiment of the present application, a six-degree-of-freedom passive vibration isolator includes: a housing 100, a support platform 200, an adjustment platform 300, a main platform 400, a secondary platform 500, a tabletop 600, a plurality of horizontal adjustment mechanisms 700 and a vertical adjustment mechanism 800.

The housing 100 is configured with a top opening, a closed bottom, and an inner cavity; wherein the housing 100 includes a base plate 900, a plurality of slide rails 130 are arranged on the inner wall of the housing near the top surface 110 of the housing 100; a support plate 140 is fixedly connected to the inner wall of the housing 100 near the bottom surface 120 of the housing 100, the support plate 140 and the base plate 900 are in parallel.

Each of the slide rails 130 extends in a direction parallel to the central axis of the housing 100, and is attached to and fixedly connected to the inner wall of the housing 100.

The support platform 200 is a circular plate, and disposed on the support plate 140, wherein a plurality of first through holes 210 are formed in the support platform, the first through holes 210 are arranged circumferentially around the central axis of the support platform 200; a plurality of second through holes 220 are formed in the support platform 200, the second through holes 220 are arranged circumferentially around the central axis of the support platform 200.

The adjustment platform 300 is a circular plate, and provided with right-angle connecting pieces 310, wherein the adjustment platform 300 is slidably connected to the slide rails 130 through the right-angle connecting pieces 310; a plurality of third through holes 320 are formed in the adjustment platform 300, the third through holes 320 are arranged circumferentially around the central axis of the adjustment platform 300; a plurality of fourth through holes 330 are formed in the adjustment platform 300, the fourth through holes 330 are arranged circumferentially around the central axis of the adjustment platform 300.

The main platform 400 is accommodated within the inner cavity of the housing 100, wherein a plurality of fifth through holes 420 are formed in the main platform 400.

The main platform is fixedly connected to the adjustment platform 300 through the vertical spring 410.

The first through holes 210, the third through holes 320, and the fifth through holes 420 are located on a straight line parallel to the central axis of the housing 100.

The second through holes 220 and the fourth through holes 320 are located on another straight line parallel to the central axis of the housing 100.

The secondary platform 500 is accommodated within the inner cavity of the housing 100.

The vertical connecting rod 510 is accommodated within the second through holes 220 and the fourth through holes 330, wherein the secondary platform 500 is fixedly connected to the main platform 400 through the vertical connecting rod 510.

The tabletop 600 is located outside the housing 100.

The Euler compression rod 610 is accommodated within the first through holes 210, the third through holes 320, and the fifth through holes 420, wherein the tabletop 600 is fixedly connected to the secondary platform 500 through the Euler compression rod 610.

Each of the plurality of horizontal adjustment mechanisms 700 is connected to the main platform 400.

The vertical adjustment mechanism 800 is located between the adjustment platform 300 and the support platform 200.

Specifically, the housing 100 can be a hollow cylinder with a top opening, a closed bottom, and an inner cavity.

The six-degree-of-freedom interference in space includes six directions: translation along the X-axis, Y-axis, and Z-axis, and rotation around the X-axis, Y-axis, and Z-axis. Adding a prismatic pair 881 and a sphere-pin pair 880 at the center of the main platform 400 ensures that main platform 400 has only three degrees of freedom along the Z-axis translation direction and rotation around the X-axis and Y-axis. Meanwhile, the same-length Euler compression rod 610 ensures that tabletop 600 has only three degrees of freedom along the X-axis and Y-axis translation directions and rotation around the Z-axis relative to the main platform 400. The vibration interference from the base plate 900 is transmitted to the main platform 400 through the compression spring quasi-zero stiffness structure composed of a plurality of vertical springs 410 between the main platform 400 and the adjustment platform 300 and a plurality of horizontal adjustment mechanisms 700 between the main platform 400 and the housing 100, to isolate and suppress the interference in the linear direction of the Z axis and the rotational direction around the X axis and the Y axis; the main platform 400 is fixedly connected to the secondary platform 500 through the rigid vertical connecting rod 510, and its movement is consistent with the main platform 400. The vibration interference reaching the secondary platform 500 is transmitted to the tabletop 600 through the Euler compression rod 610, and the Euler compression rod 610 isolates the vibration in the linear direction of the X axis and the Y axis and the rotational direction around the Z axis. Finally, the tabletop 600 is fixedly connected to the load. After two-stage suppression, the vibration interference is finally transmitted to the load. Each level of vibration isolation system isolates the vibration interference in three directions of space to achieve the effect of six-degree-of-freedom vibration isolation, so that the six-degree-of-freedom passive vibration isolator can adapt to complex vibration interference environments.

The six-degree-of-freedom passive vibration isolator described in the present application realizes six-degree-of-freedom vibration isolation in space, so that the six-degree-of-freedom passive vibration isolator can adapt to complex vibration interference environments. Furthermore, under the vibration excitation of the standard vertical table, horizontal platform, corner table, and swing table, the acceleration transmissibility frequency response characteristics of each single-degree-of-freedom vibration quantity of the six-degree-of-freedom passive vibration isolator are observed. The natural frequencies of the isolator in the horizontal, vertical, swing, and torsional directions are all less than 2.5 Hz, which demonstrates the vibration isolation effect of the six-degree-of-freedom passive vibration isolator. The multi-degree-of-freedom passive vibration isolator is simple in structure, low in analysis difficulty, and easy and convenient in use.

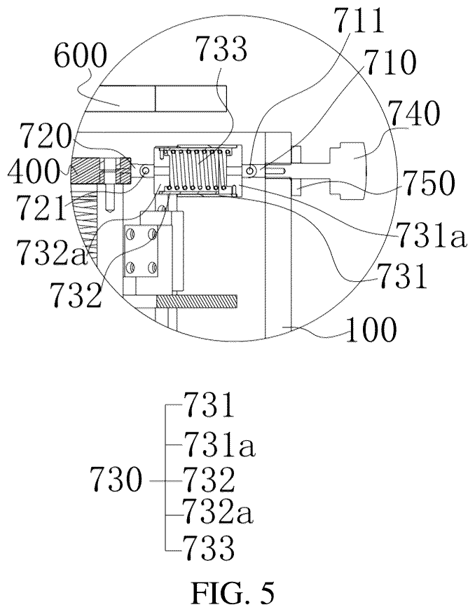

As shown in FIG. 5, in an embodiment of the present application, each of the horizontal adjustment mechanisms 700 includes a first revolute joint connecting piece 710, a second revolute joint connecting piece 720, and a horizontal damping spring 730.

One end of the first revolute joint connecting piece 710 abuts against the inner wall of the housing 100, a first rotating shaft 711 is arranged at the other end of the first revolute joint connecting piece 710, the central axis of the first rotating shaft 711 is parallel to the support platform 200.

one end of the second revolute joint connecting piece 720 abuts against the main platform 400, a second rotating shaft 721 is arranged at the other end of the second revolute joint connecting piece 720, the central axis of the second rotating shaft 721 is parallel to the support platform 200.

Both ends of the horizontal damping spring 730 are hinged to the first rotating shaft 711 and the second rotating shaft 721, respectively.

Specifically, the main platform 400 is connected to the housing 100 by the first revolute joint connecting piece 710, the second revolute joint connecting piece 720 and the horizontal damping spring 730. Since the first revolute joint connecting piece 710 is provided with a first rotating shaft 711 and the second revolute joint connecting piece 720 is provided with a second rotating shaft 721, when the main platform 400 is subjected to vibrations in the rotation directions around the X axis and around the Y axis, the first rotating shaft 711 and the second rotating shaft 721 can provide a fulcrum for the torque for the main platform 400 in the rotation directions around the X axis and around the Y axis. Thus, vibration isolation in the rotation directions around the X axis and around the Y axis is achieved.

The horizontal adjustment mechanism 700 described in the present application utilizes the first rotating shaft 711 of the first revolute joint connecting piece 710 and the second rotating shaft 721 of the second revolute joint connecting piece 720 to provide a fulcrum for the torque of the main platform 400 in the rotation directions around the X axis and around the Y axis, thereby realizing vibration isolation in the rotation directions around the X axis and around the Y axis.

As shown in FIG. 5, in an embodiment of the present application, the horizontal damping spring 730 includes an outer guide cylinder 731, an inner guide cylinder 732, and a horizontal spring 733.

The outer guide cylinder 731 is a hollow cylinder; a third revolute joint connecting piece 731a is arranged at one end of the outer guide cylinder 731; the third revolute joint connecting piece 731a is hinged to the first rotating shaft 711; the other end of the outer guide cylinder 731 is slidably sleeved with the inner guide cylinder 732.

The inner guide cylinder 732 is a hollow cylinder; a fourth revolute joint connecting piece 732a is arranged at one end of the inner guide cylinder 732; the fourth revolute joint connecting piece 732a is hinged to the second rotating shaft 721.

The horizontal spring 733 is accommodated within the cylindrical cavity of the outer guide cylinder 731 and the inner guide cylinder 732; one end of the horizontal spring 733 abuts against the third revolute joint connecting piece 731a within the inner cavity of the outer guide cylinder 731; and the other end of the horizontal spring 733 abuts against the fourth revolute joint connecting piece 732a within the inner cavity of the inner guide cylinder 732.

Specifically, the outer guide cylinder 731 and the inner guide cylinder 732 are nested with each other. Since the contact surface between the outer guide cylinder 731 and the inner guide cylinder 732 is smooth, the outer guide cylinder 731 and the inner guide cylinder 732 can move in the rotation directions around the X axis and around the Y axis. More specifically, the outer guide cylinder 731 and the inner guide cylinder 732 can rotate around the central axes thereof. It is worth mentioning that the third revolute joint connecting piece 731a is hinged with the first rotating shaft 711, and the fourth revolute joint connecting piece 732a is hinged with the second rotating shaft 721, which can isolate the vibrations in the rotation directions around the X axis and around the Y axis.

The horizontal damping spring 730 described in the present application mainly provides negative stiffness force and torque for the rotation directions around the X axis and around the Y axis, adjusts the compression amount of the horizontal spring 733, and constrains the degree of freedom of the main platform 400. The third revolute joint connecting piece 731a is fixedly connected to the outer guide cylinder 731, and the fourth revolute joint connecting piece 732a is fixedly connected to the inner guide cylinder 732. The inner and outer guide cylinders form a cylindrical sleeve pair through clearance fit, which has the degree of freedom of rotation around the X axis and the Y axis. This allows the main platform 400 to achieve vibration isolation in the rotation directions around the X axis and the Y axis.

As shown in FIG. 5, in an embodiment of the present application, each of the horizontal adjustment mechanisms 700 further includes a horizontal knob 740 and a fastening nut 750.

The housing 100 is provided with a plurality of threaded through holes 150 on the column wall.

A screw rod preset portion of the horizontal knob 740 is accommodated within the threaded through hole 150, one end of the screw rod of the horizontal knob 740 is located inside the housing 100 and fixedly connected to the first revolute joint connecting piece 710, and the other end of the screw rod of the horizontal knob 740 is located outside the housing 100.

The screw rod of the fastening nut 750 sleeved on the horizontal knob 740 is located at a preset position outside the housing 100 and fits with the outer wall of the housing 100.

Specifically, the horizontal adjustment mechanism 700 faces complex vibrations during operation, and the threaded connection between the horizontal knob 740 and the threaded through hole 150 is susceptible to vibration. When there is no fastening nut 750, the horizontal knob 740 will rotate around the central axis of the threaded through hole 150 under the action of vibration, especially under the action of the horizontal spring 733, the horizontal knob 740 will move away from the main platform 400 along the axial direction. However, when the horizontal knob 740 moves away from the main platform 400 along the axial direction, the horizontal spring 733 cannot constrain the degree of freedom of the main platform 400, which leads to reduction in the vibration isolation ability in the rotation directions around the X axis and around the Y axis. Therefore, the fastening nut 750 is required to be sleeved on the screw rod of the horizontal knob 740 at a preset position outside the housing 100 and fit with the outer wall of the housing 100. The fastening nut 750 relies on a frictional force to lock the horizontal knob 740.

When the main platform 400 is in a quasi-zero stiffness position for the horizontal knob 740 described in the present application, the main platform 400 and the horizontal spring 733 are on the same horizontal plane. By rotating and controlling the first revolute joint connecting piece 710 to move forward or backward, the horizontal spring 733 is compressed or extended, thereby adjusting the stiffness of the main platform 400 in the rotation directions around the X-axis and around the Y-axis, solving the problem that the multi-degree-of-freedom parameters cannot be adjusted. Meanwhile, the fastening nut 750 relies on a frictional force to lock the horizontal knob 740 to prevent the horizontal knob 740 from moving away from the main platform 400 in the axial direction.

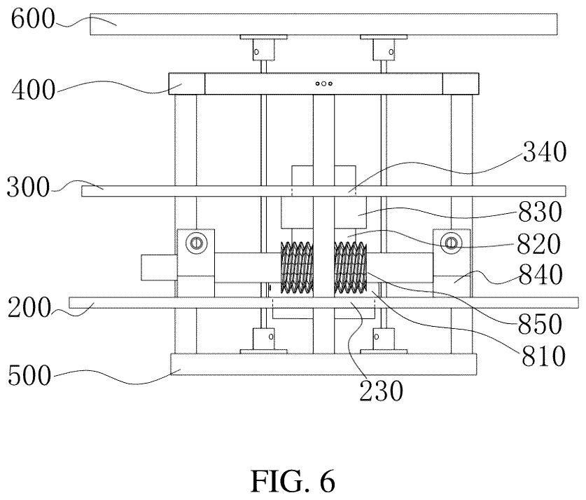

As shown in FIG. 6, in an embodiment of the present application, the vertical adjustment mechanism 800 includes a worm gear 810, a feed screw rod 820 and a linear bearing 830.

The adjustment platform 300 is provided with a sixth through hole 340 at the center.

The support platform 200 is provided with a seventh through hole 230 at the center.

The worm gear 810 is rotatably sleeved on the seventh through hole 230.

The linear bearing 830 is clamped on the sixth through hole 340.

One end of the feed screw rod 820 is fixed to the center of the worm gear 810, and the other end of the feed screw rod 820 is sleeved on the linear bearing 830.

Specifically, the linear bearing 830 is clamped in the sixth through hole 340, and the worm gear 810 is rotatably mounted on the seventh through hole 230. When the worm gear 810 rotates, one end of the feed screw rod 820 is fixed to the center of the worm gear 810, and the worm gear 810 drives the feed screw rod 820 to rotate. The other end of the feed screw rod 820 is sleeved on the linear bearing 830. The rotating feed screw rod 820 enables the linear bearing 830 to drive the adjustment platform 30 to move along the central axis direction of the housing 100, thus achieving a change in the compression amount of the vertical spring 410.

The worm gear 810, feed screw rod 820 and linear bearing 830 described in the present application enable the adjustment platform 300 to move along the central axis direction of the housing 100, change the compression amount of the vertical spring 410, and then constrain the vertical degree of freedom of the main platform 400. When the main platform 400 is working, the tabletop 600 is subjected to the gravity of the load, and the tabletop 600 will transfer the gravity of the load to the main platform 400. Therefore, before starting vibration isolation, it is necessary to change the position of the adjustment platform 300 through the worm gear 810, feed screw rod 820 and linear bearing 830 to change the compression amount of the vertical spring 410, so as to achieve the quasi-zero stiffness position of the main platform 400, which can adapt to loads of different masses and solve the problem that the parameters of multiple degrees of freedom cannot be adjusted. It is worth mentioning that whether the main platform 400 is in a quasi-zero stiffness position directly affects the vibration isolation effect in all directions.

As shown in FIG. 6, in an embodiment of the present application, the vertical adjustment mechanism 800 further includes a pair of shaft seats 840 and a worm 850.

The shaft seats 840 are fixed to the support platform 200.

Two ends of the worm 850 are smooth, and the two ends of the worm 850 are rotatably sleeved on the pair of shaft seats 840, and the worm 850 is meshed with the worm gear 810.

Specifically, the smoothness of the two ends of the worm 850 ensures that the worm 850 has no axial movement on the shaft seat 840. The worm 850 is meshed with the worm gear 810. When the worm 850 is rotated, the worm 850 drives the worm gear 810 to rotate. The size of the housing 100 determines the envelope volume of the six-degree-of-freedom passive vibration isolator. Therefore, in order to maximize the use of the housing 100 space, the support platform 200, the adjustment platform 300 and the main platform 400 move in the vertical direction. The worm 850 rotating around the horizontal axis can drive the worm gear 810 rotating around the vertical direction, so that the support platform 200, the adjustment platform 300 and the main platform 400 move in the vertical direction.

The shaft seat 840 and the worm 850 described in the present application solve the problem that the multi-degree-of-freedom parameters cannot be adjusted, and maximize the use of the housing 100 space, reducing the volume and weight of the six-degree-of-freedom passive vibration isolator system. The problems of large volume and lack of flexibility of the existing six-degree-of-freedom passive vibration isolator are solved.

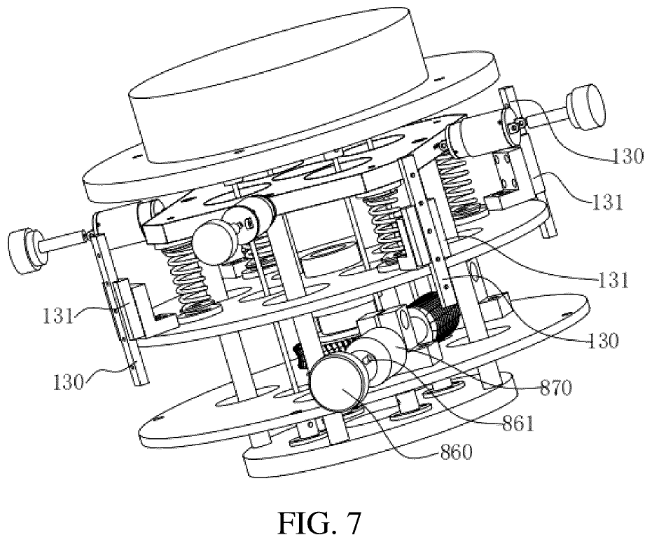

As shown in FIG. 7, in an embodiment of the present application, the vertical adjustment mechanism 800 further includes a knob 860 and a coupling 870.

The housing 100 is provided with an eighth through hole 160.

The preset part of the knob 860 is accommodated in the eighth through hole 160, one end of the knob 860 is located inside the housing 100 and is flexibly connected to one end of the worm 850 through the coupling 870, and the other end of the knob 860 is located outside the housing 100 and is provided with a locking screw 861.

Specifically, when the main platform 400 is not in the quasi-zero stiffness position, the knob 860 is rotated, and the knob 860 drives the worm 850 to rotate through the coupling 870, drives the worm gear 810 to rotate, and then drives the feed screw rod 820 to rotate, and drives the adjustment platform 300 to move vertically up and down, thereby adjusting the main platform 400 to the quasi-zero stiffness position. When the main platform 400 is adjusted to the quasi-zero stiffness position, the locking screw 861 locks the worm 850 so that the worm does not rotate around the horizontal axis.

The knob 860 described in the present application provides a device for adjusting the vertical degree of freedom of the six-degree-of-freedom passive vibration isolator. A part of the knob 860 is outside the housing 100, which facilitates the operator to directly adjust the position of the six-degree-of-freedom passive vibration isolator main platform 400. Meanwhile, a coupling 870 is used between the knob 860 and the worm 850 to reduce the error when mounting the equipment.

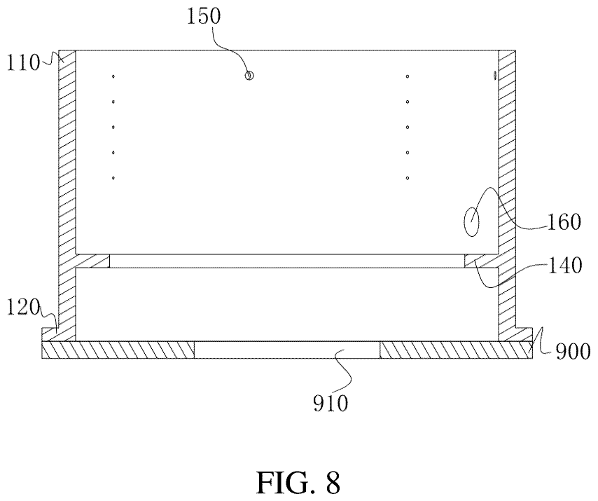

As shown in FIG. 8, in an embodiment of the present application, the support plate 140 is an annular plate, the outer edge of the support plate 140 is fixedly connected to the inner wall of the housing 100, and the central axis of the inner edge of the support plate 140 coincides with the central axis of the housing 100.

Specifically, the support plate 140 is used to place the support platform 200. The support plate is an annular plate with a circular hole in the center. On the one hand, the circular hole is conducive to the mounting of the worm gear 810 on the support platform 200, and on the other hand, the circular hole accommodates an extension portion of the worm gear 810.

The support plate 140 described in the present application provides an mounting site for the support platform 200, which is conducive to the mounting of the worm gear 810 on the support platform 200 and accommodates the extension portion of the worm gear 810. It ensures that the support platform 200 plays a bearing role, and more importantly, it couples the vibration between the support platform 200 and the housing 100.

As shown in FIG. 7, in an embodiment of the present application, one right-angle side of the right-angle connecting piece 310 is fixedly connected to the adjustment platform 300, and the other right-angle side of the right-angle connecting pieces 310 is fixedly connected to the sliding block 131, and the sliding block 131 is slidably sleeved on the slide rail 130.

Specifically, the adjustment platform 300 is connected to the sliding block 131 and the slide rail 130 through multiple right-angle connecting pieces 310, and the slide rail 130 is fixedly connected to the housing 100. The right-angle connecting pieces 310 enable the adjustment platform 300 to move in the vertical direction.

The right-angle connecting pieces 310 described in the present application ensure that the adjustment platform 300 moves in the vertical direction. The right-angle connecting pieces 310 play a role in limiting the adjustment platform 300 after being connected to the sliding block 131 and the slide rail 130.

As shown in FIG. 8, in an embodiment of the present application, the center of the base plate 900 is provided with a ninth through hole 910, and the ninth through hole 910 is used to mount the six-degree-of-freedom passive vibration isolator on the vibration source.

Specifically, a second end 120 of the housing 100 is connected to the vibration source, and the base plate 900 is provided with a ninth through hole 910, which is used for the operator to reach into the housing 100 to mount the various mounting nuts on the support platform 200. The ninth through hole is also used as a mounting hole to leave a mounting space for the components mounted on the secondary platform 500 to avoid assembly problems. Meanwhile, the ninth through hole 910 is also adapted to the mechanical structure of the vibration source.

The base plate 900 described in the present application mainly serves to connect the vibration source, so that the operator can mount various mounting nuts on the support platform 200. More importantly, when debugging the six-degree-of-freedom passive vibration isolator, a mass center compensation block can be placed on the secondary platform 500 through the ninth through hole 910 on the base plate 900. The mass center compensation block can adjust the overall mass center position when a load is placed on the tabletop 600 of the six-degree-of-freedom passive vibration isolator, so that the overall mass center position meets the requirements of the quasi-zero stiffness position.

The technical features of the foregoing embodiments can be combined arbitrarily, and the execution order of various methods and steps is not limited. In order to make the description concise, not all possible combinations of the technical features in the foregoing embodiments are described. However, as long as there is no contradiction, the combinations of these technical features shall be considered to fall within the scope described in the specification.

The foregoing embodiments merely describe several implementation methods of the present application, and the description is relatively specific and detailed, but cannot be understood as a limitation on the scope of the patent of the present application. It should be noted that several modifications and improvements can be made by a person of ordinary skill in the art without departing from the concept of the present application, and all these modifications and improvements shall fall within the scope of protection of the present application. Therefore, the scope of protection of the present application shall be defined by the appended claims.

What is claimed is:

1. A method for applying a six-degree-of-freedom passive vibration isolator, comprising:
judging the working mode of a vibration isolation model by utilizing static stiffness characteristics and dynamic stiffness characteristics within quasi-zero stiffness characteristics of the vibration isolation model to obtain the working mode of the vibration isolation model;
judging whether the static stiffness characteristics of the vibration isolation model match the degrees of freedom of the vibration isolation model based on the working mode of the vibration isolation model to obtain the type of the vibration isolation model;
extracting all types of vibration isolation models, including a passive vibration isolation system in an active vibration isolation system model and a hybrid vibration isolation system model;
incorporating the passive vibration isolation system and the passive vibration isolation system model into the quasi-zero-stiffness analysis algorithm to obtain an adaptive structural parameter system for degree-of-freedom analysis;
generating a coupling effect characteristic equation based on the adaptive structural parameter system for degree-of-freedom analysis; and
generating a degree-of-freedom passive vibration isolator by utilizing the coupling effect characteristic equation.

2. The method for applying the six-degree-of-freedom passive vibration isolator according to claim 1, wherein the judging the working mode of a vibration isolation model by utilizing static stiffness characteristics and dynamic stiffness characteristics within quasi-zero stiffness characteristics of the vibration isolation model to obtain the working mode of the vibration isolation mode, comprises:
the working mode of the vibration isolation model comprises one or more of a degree-of-freedom working mode, a load type working mode, or a coupler working mode.

3. The method for applying the six-degree-of-freedom passive vibration isolator according to claim 2, wherein the judging whether the static stiffness characteristics of the vibration isolation model match the degrees of freedom of the vibration isolation model based on the working mode of the vibration isolation model to obtain the type of the vibration isolation model, comprises:
judging the working mode of a vibration isolation model by utilizing static stiffness characteristics and dynamic stiffness characteristics within quasi-zero stiffness characteristics of the vibration isolation model to obtain the working mode of the vibration isolation model;
judging whether the static stiffness characteristics of the vibration isolation model match the degrees of freedom of the vibration isolation model based on the working mode of the vibration isolation model;
if the static stiffness characteristics of the vibration isolation model match the degrees of freedom of the vibration isolation model, further judging whether the coupling effect of the coupler of the vibration isolation model matches the dynamic stiffness characteristics;
if the coupling effect of the coupler matches the dynamic stiffness characteristics, determining the vibration isolation model as a passive vibration isolation model; and
if the coupling effect of the coupler does not match the dynamic stiffness characteristics, determining the vibration isolation model as an active vibration isolation model.

4. The method for applying the six-degree-of-freedom passive vibration isolator according to claim 3, wherein the judging whether the static stiffness characteristics of the vibration isolation model match the degrees of freedom of the vibration isolation model based on the working mode of the vibration isolation model to obtain the type of the vibration isolation model, further comprises:
judging the working mode of a vibration isolation model by utilizing static stiffness characteristics and dynamic stiffness characteristics within quasi-zero stiffness characteristics of the vibration isolation model to obtain the working mode of the vibration isolation model;
judging whether the static stiffness characteristics of the vibration isolation model match the degrees of freedom of the vibration isolation model based on the working mode of the vibration isolation model;
if the static stiffness characteristics of the vibration isolation model do not match the degrees of freedom of the vibration isolation model, further judging whether the coupler of the vibration isolation model matches the native characteristics of the vibration isolation model;
if the coupler matches the native characteristics of the vibration isolation model, determining the vibration isolation model as a hybrid vibration isolation model; and
if the coupler does not match the native characteristics of the vibration isolation model, determining the vibration isolation model as an active vibration isolation model.

5. The method for applying the six-degree-of-freedom passive vibration isolator according to claim 4, wherein the extracting the passive vibration isolation system of all vibration isolation models, comprises:
the types of vibration isolation models comprise active vibration isolation system models and hybrid vibration isolation system models.

6. The method for applying the six-degree-of-freedom passive vibration isolator according to claim 5, wherein the extracting the passive vibration isolation system of all vibration isolation models, further comprises:
judging whether an applied vibration isolation model is a passive vibration isolation model based on a target application scenario;
if the vibration isolation model is a passive vibration isolation model, establishing a passive vibration isolation system model based on the passive vibration isolation model;
if the vibration isolation model is an active vibration isolation model, further judging whether the vibration isolation model is an active vibration isolation system model;
if the vibration isolation model is an active vibration isolation system model, establishing an active vibration isolation system model based on the active vibration isolation system model; and
if the vibration isolation model is not an active vibration isolation system model, establishing a hybrid vibration isolation system model.

7. The method for applying the six-degree-of-freedom passive vibration isolator according to claim 6, wherein the judging whether an applied vibration isolation model is a passive vibration isolation model based on a target application scenario, comprises:
determining a load type;
selecting the parameters of a vibration isolation platform based on the load type; and
selecting the vibration isolation model using the parameters of the vibration isolation platform.

8. The method for applying the six-degree-of-freedom passive vibration isolator according to claim 7, wherein the judging whether an applied vibration isolation model is a passive vibration isolation model based on a target application scenario, further comprises:
judging whether a vibration isolation platform linkage feature of the selected vibration isolation model has a fixed connection feature;
if the vibration isolation platform linkage feature of the selected vibration isolation model does not have a fixed connection feature, determining that the quasi-zero stiffness characteristics of the vibration isolation model are less than the quasi-zero stiffness accuracy in quasi-zero stiffness applications;
if the selected vibration isolation model has a fixed connection feature, further judging whether the vibration isolation platform of the selected vibration isolation model has a follow-up characteristic;
if the vibration isolation platform of the selected vibration isolation model does not have a follow-up characteristic, determining an actuator adapted to the vibration isolation model so that a numerical value of the quasi-zero stiffness characteristics of the vibration isolation model is greater than or equal to the quasi-zero stiffness accuracy in quasi-zero stiffness applications; and
if the vibration isolation platform of the selected vibration isolation model has a follow-up characteristic, determining that the numerical value of the quasi-zero stiffness characteristics of the vibration isolation model is greater than or equal to the quasi-zero stiffness accuracy in quasi-zero stiffness applications.

9. The method for applying the six-degree-of-freedom passive vibration isolator according to claim 8, wherein if the vibration isolation model is a passive vibration isolation model, establishing a passive vibration isolation system model, comprises:
determining an equilibrium position of the vibration isolation model based on the quasi-zero stiffness characteristics of the vibration isolation model;
determining the positive and negative stiffness parallel characteristics of the vibration isolation model using the equilibrium position of the vibration isolation model; and
analyzing the static stiffness characteristics and dynamic stiffness characteristics of the quasi-zero stiffness characteristics of the vibration isolation model based on the positive and negative stiffness parallel characteristics of the vibration isolation model.

10. The method for applying the six-degree-of-freedom passive vibration isolator according to claim 9, wherein the extracting the passive vibration isolation system from the active vibration isolation system model and the hybrid vibration isolation system model, comprises:
analyzing the vibration isolation of a compression spring quasi-zero stiffness structure in the passive vibration isolation system of the active vibration isolation system model and the hybrid vibration isolation system model;
obtaining the native characteristics and coupling effect characteristics of the coupler;
analyzing the vibration isolation of an Euler compression rod quasi-zero stiffness structure in the passive vibration isolation system of the active vibration isolation system model and the hybrid vibration isolation system model;
obtaining degree-of-freedom adaptive structural parameters of the vibration isolation model; and
determining a quasi-zero-stiffness degree-of-freedom passive vibration isolation system analysis equation based on the adaptive structural parameters and the degree-of-freedom adaptive structural parameters of the vibration isolation model.

11. The method for applying the six-degree-of-freedom passive vibration isolator according to claim 10, wherein the incorporating the passive vibration isolation system and the passive vibration isolation system model into the quasi-zero-stiffness analysis algorithm to obtain an adaptive structural parameter system for degree-of-freedom analysis, comprises a quasi-zero-stiffness analysis algorithm:
the quasi-zero-stiffness analysis algorithm comprises:
a vertical spring analysis equation;
a horizontal adjustment mechanism analysis equation;
a main platform assembly analysis equation;
an Euler compression rod mechanism analysis equation; and
a vertical adjustment mechanism analysis equation.

12. A six-degree-of-freedom passive vibration isolator, comprising:
a housing, configured with a top opening, a closed bottom, and an inner cavity, wherein the housing comprises a base plate, a plurality of slide rails are arranged on the inner wall of the housing near the top surface of the housing; a support plate is fixedly connected to the inner wall of the housing near the bottom surface of the housing, the support plate and the base plate are in parallel;
each of the slide rails extends in a direction parallel to the central axis of the housing, and is attached to and fixedly connected to the inner wall of the housing;
a support platform, configured as a circular plate, and disposed on the support plate, wherein a plurality of first through holes are formed in the support platform, the first through holes are arranged circumferentially around the central axis of the support platform; a plurality of second through holes are formed in the support platform, the second through holes are arranged circumferentially around the central axis of the support platform;
an adjustment platform, configured as a circular plate, and provided with right-angle connecting pieces, wherein the adjustment platform is slidably connected to the slide rails through the right-angle connecting pieces; a plurality of third through holes are formed in the adjustment platform, the third through holes are arranged circumferentially around the central axis of the adjustment platform; a plurality of fourth through holes are formed in the adjustment platform, the fourth through holes are arranged circumferentially around the central axis of the adjustment platform;
a main platform, accommodated within the inner cavity, wherein a plurality of fifth through holes are formed in the main platform;
a vertical spring, wherein the main platform is fixedly connected to the adjustment platform through the vertical spring;
the first through holes, the third through holes, and the fifth through holes are located on a straight line parallel to the central axis of the housing;
the second through holes and the fourth through holes are located on another straight line parallel to the central axis of the housing;
a secondary platform, accommodated within the inner cavity of the housing;
a vertical connecting rod, accommodated within the second through holes and the fourth through holes, wherein the secondary platform is fixedly connected to the main platform through the vertical connecting rod;
a tabletop, located outside the housing;
an Euler compression rod, accommodated within the first through holes, the third through holes, and the fifth through holes, wherein the tabletop is fixedly connected to the secondary platform through the Euler compression rod;
a plurality of horizontal adjustment mechanisms, each connected to the main platform; and
a vertical adjustment mechanism, located between the adjustment platform and the support platform.

13. The six-degree-of-freedom passive vibration isolator according to claim 12, wherein each of the horizontal adjustment mechanisms comprises a first revolute joint connecting piece, a second revolute joint connecting piece, and a horizontal damping spring;
one end of the first revolute joint connecting piece abuts against the inner wall of the housing, a first rotating shaft is arranged at the other end of the first revolute joint connecting piece, the central axis of the first rotating shaft is parallel to the support platform;
one end of the second revolute joint connecting piece abuts against the main platform, a second rotating shaft is arranged at the other end of the second revolute joint connecting piece, the central axis of the second rotating shaft is parallel to the support platform; and
both ends of the horizontal damping spring are hinged to the first rotating shaft and the second rotating shaft, respectively.

14. The six-degree-of-freedom passive vibration isolator according to claim 13, wherein the horizontal damping spring comprises an outer guide cylinder, an inner guide cylinder, and a horizontal spring;
the outer guide cylinder is a hollow cylinder, a third revolute joint connecting piece is arranged at one end of the outer guide cylinder, the third revolute joint connecting piece is hinged to the first rotating shaft, the other end of the outer guide cylinder is slidably sleeved with the inner guide cylinder;
the inner guide cylinder is a hollow cylinder, a fourth revolute joint connecting piece is arranged at one end of the inner guide cylinder, the fourth revolute joint connecting piece is hinged to the second rotating shaft;
the horizontal spring is accommodated within the cylindrical cavity of the outer guide cylinder and the inner guide cylinder, one end of the horizontal spring abuts against the third revolute joint connecting piece within the inner cavity of the outer guide cylinder, and the other end of the horizontal spring abuts against the fourth revolute joint connecting piece within the inner cavity of the inner guide cylinder.
